(19) United States
(12) Patent Application Publication
(10) Pub. No.: US 2015/0077680 A1
(43) Pub. Date: Mar. 19, 2015

(54) METHOD OF MANUFACTURING DISPLAY SUBSTRATE, DISPLAY PANEL AND DISPLAY APPARATUS HAVING THE DISPLAY PANEL

(71) Applicant: SAMSUNG DISPLAY CO., LTD., YONGIN-CITY (KR)

(72) Inventors: BYEONG-HEE WON, HWASEONG-SI (KR); JOON-HAK OH, SEOUL (KR)

(21) Appl. No.: 14/470,230

(22) Filed: Aug. 27, 2014

(30) Foreign Application Priority Data
Sep. 13, 2013 (KR) 10-2013-0110225

(51) Int. Cl. G02F 1/1368; G02F 1/1335; H01L 27/15; G02F 1/1362; G02F 1/133; H01L 27/12; G02F 1/1333

(52) U.S. Cl. CPC G02F 1/1368; H01L 27/1259; G02F 1/133514; G02F 1/133345; G02F 1/136227; G02F 1/136286; G02F 1/13306; H01L 27/15
USPC 349/46; 438/151; 349/42; 257/89

(57) ABSTRACT

A method of manufacturing a display substrate includes forming a plurality of gate lines, a plurality of data lines and a plurality of transistors on a base substrate, forming an insulating layer on the base substrate on which the transistors are formed and forming a first pixel electrode on the insulating layer in a first area of a pixel area. The pixel area is divided into the first area and a second area.

This application claims priority to Korean Patent Application No. 10-2013-0110225 filed on Sep. 13, 2013, the disclosure of which is hereby incorporated by reference herein in its entirety.

### 1. TECHNICAL FIELD

The present disclosure relates to a method of manufacturing a display substrate, a display apparatus having the display substrate and a display apparatus having the display panel. More particularly, the present disclosure relates to a method of manufacturing a display substrate for increasing display quality, a display apparatus having the display substrate and a display apparatus having the display panel.

### 2. DISCUSSION OF THE RELATED ART

Generally, a liquid crystal display (LCD) apparatus includes, for example, an LCD panel displaying images using the transmittance of a liquid crystal, and a backlight assembly disposed under the LCD panel and providing light to the LCD panel.

The LCD panel includes a lower substrate, a liquid crystal (LC) layer and an upper substrate. The lower substrate may include, for example, a plurality of gate lines, a plurality of data lines and a plurality of pixel electrodes. The upper substrate is disposed opposite to the lower substrate. The upper substrate may include, for example, a plurality of color filters which are disposed to overlap with the pixel electrodes and a common electrode disposed opposite to the pixel electrodes. The color filters may include, for example, red filters, green filters and blue filters.

The liquid crystal display panel may include, for example, a sub-pixel in which the pixel electrode is formed. The sub-pixel includes, for example, the pixel electrode and a color filter corresponding to the pixel electrode. The backlight assembly generates white light and then the sub-pixel transmits a color light through the color filter. Thus, the sub-pixel may display a color image. However, as the color filter overlaps with the pixel electrode, the transmittance of the sub-pixel may be decreased.

### SUMMARY OF THE INVENTION

Exemplary embodiments of the present invention provide a method of manufacturing of a display substrate for increased display quality.

Exemplary embodiments of the present invention provide a display panel having the display substrate.

Exemplary embodiments of the present invention provide a display apparatus having the display panel.

According to an exemplary embodiment of the invention, there is provided a method of manufacturing a display substrate. The method includes forming a plurality of gate lines, a plurality of data lines and a plurality of transistors on a base substrate, forming an insulating layer on the base substrate on which the transistors are formed and forming a first pixel electrode on the insulating layer in a first area of a pixel area. The pixel area is divided into the first area and a second area.

In an exemplary embodiment, the forming of the first pixel electrode may include forming a first contact hole in the insulating layer to expose a drain electrode of one of the transistors, forming a transparent conductive layer on the base substrate on which the first contact hole is formed and patterning the transparent conductive layer to form the first pixel electrode on the insulating layer in the first area and to expose the insulating layer in the second area.

In an exemplary embodiment, the forming the plurality of transistors may include forming a plurality of signal lines which are disposed between the gate lines.

In an exemplary embodiment, the plurality of signal lines may be formed from a same metal layer as the gate lines.

In an exemplary embodiment, the forming of the first pixel electrode may include forming a first contact hole in the insulating layer to expose a drain electrode of one of the transistors, forming a second contact hole in the insulating layer to expose a signal line disposed between the gate lines, forming a transparent conductive layer on the base substrate on which the first contact hole and the second contact hole are formed and patterning the transparent conductive layer to form the first pixel electrode on the insulating layer in the first area and to form a second pixel electrode on the insulating layer in the second area.

In an exemplary embodiment, the first pixel electrode may be connected to the drain electrode of the one of the transistors through the first contact hole, and the second pixel electrode is connected to the signal line through the second contact hole.

In an exemplary embodiment, the forming the plurality of transistors may include forming a connection line which is connected to an end portion of the signal line.

According to an exemplary embodiment of the invention, there is provided a display panel. The display panel includes a first display substrate including a first pixel electrode which is disposed in a first area of a pixel area, and a transistor which is connected to the first pixel electrode. The pixel area is divided into the first area and a second area. The display panel further includes a second display substrate including a color filter which is disposed in an area corresponding to the first area of the pixel area and a liquid crystal layer disposed between the first and second display substrates.

In an exemplary embodiment, the liquid crystal layer may have a normally white mode.

In an exemplary embodiment, the first display substrate may further include an insulating layer which is disposed between the first pixel electrode and the transistor, and the second display substrate may further include a common electrode.

In an exemplary embodiment, the liquid crystal layer in the first area may be disposed between the common electrode and the first pixel electrode, and the liquid crystal layer in the second area may be disposed between the common electrode and the insulating layer.

In an exemplary embodiment, the first display substrate may further include a gate line which is connected to a gate electrode of the transistor and a data line which is connected to a source electrode of the transistor. The first pixel electrode may be connected to a drain electrode of the transistor through a first contact hole.

In an exemplary embodiment, the first display substrate may further include a signal line which is disposed between the gate lines and a second pixel electrode is spaced apart from the first pixel electrode. The second pixel electrode is disposed in the second area and is connected to the signal line through a second contact hole.

In an exemplary embodiment, the first display substrate may further include a plurality of signal lines and a connection line which is connected to end portions of the signal lines.

According to an exemplary embodiment of the invention, there is provided a display apparatus. The display apparatus includes a display panel including a first display substrate which includes a first pixel electrode disposed in a first area of a pixel area and a transistor which is connected to the first pixel electrode, in which the pixel area is divided into the first area and a second area, and a second display substrate which includes s a color filter overlapping with the first pixel electrode and disposed in the first area and a main driving part configured to drive the display panel.

In an exemplary embodiment, the display panel may further include a liquid crystal layer which is disposed between the first and second display substrates and has a normally white mode.

In an exemplary embodiment, the display panel may further include a second pixel electrode which is spaced apart from the first pixel electrode and disposed in the second area.

In an exemplary embodiment, the display panel may further include a gate line which is connected to the transistor, a data line which crosses the gate line and a signal line which is disposed between the gate lines and is connected to the second pixel electrode.

In an exemplary embodiment, the second pixel electrode may be connected to the signal line through a contact hole.

In an exemplary embodiment, the display panel may further include a connection line which is connected to end portions of a plurality of signal lines, and the main driving part is configured to provide the connection line with a driving signal to drive the second pixel electrode.

In accordance with an exemplary embodiment, a method of manufacturing a display substrate is provided. The method includes forming a first metal pattern including a plurality of gate lines, a signal line and a gate electrode on a base substrate, forming a first insulating layer on the first metal pattern and the base substrate, forming an active pattern on an area of the first insulating layer overlapping with the gate electrode, forming a second metal pattern including a source electrode, a drain electrode and a plurality of data lines on the active pattern and the first insulating layer, forming a second insulating layer on the second metal pattern, the active pattern and the first insulating layer, etching the second insulating layer using a first mask to form a first contact hole in the second insulating layer exposing the drain electrode via the first contact hole, forming a transparent conductive layer on the first contact hole and the second insulating layer and patterning the transparent conductive layer through a second mask including an opening part disposed on at least a first area of a pixel area divided into the first area and a second area and a blocking part disposed on at least a portion of the second area of the pixel area to form a first pixel electrode in the first area of the pixel area which is connected to the drain electrode through the first contact hole.

According to exemplary embodiments of the present invention, a pixel electrode PE is disposed in a first area of the pixel area so that a second area of the pixel area may display a white grayscale that is the initial state unrelated to the data voltage applied to the pixel electrode PE. Thus, the transparency of a middle grayscale displayed on the pixel area may be increased and the transmittance of the pixel area may be increased. In addition, a second pixel electrode which is connected to a signal line is disposed in the second area of the pixel area so that a second pixel electrode may drive independently from a first pixel electrode in the first area of the pixel area. Thus, when the second area displays the white grayscale, the transparency of the middle grayscale may be increased. Alternatively, when the second area displays a black grayscale, a full black image may be displayed. Thus, the display quality of an image displayed on the display panel may be increased.

### BRIEF DESCRIPTION OF THE DRAWINGS

Exemplary embodiments of the present invention can be understood in more detail from the following detailed description taken in conjunction with the accompanying drawings, in which:

FIG. 1 is a plan view illustrating a display panel according to an exemplary embodiment;

FIG. 2 is a cross-sectional view illustrating the display panel taken along line I-I′ as shown in FIG. 1;

FIGS. 3A to 3C are cross-sectional views explaining a method of manufacturing a first display substrate as shown in FIG. 2;

FIG. 4 is a plan view illustrating a display panel according to an exemplary embodiment;

FIG. 5 is cross-sectional view illustrating the display panel taken along line II-IF as shown in FIG. 4;

FIGS. 6A to 6C are cross-sectional views explaining a method of manufacturing a first display substrate as shown in FIG. 5;

FIG. 7 is a plan view illustrating a display apparatus according to an exemplary embodiment; and

FIG. 8 is a waveform view illustrating a method of driving the display panel shown in FIG. 5.

### DETAILED DESCRIPTION OF EXEMPLARY EMBODIMENTS OF THE INVENTION

Hereinafter, exemplary embodiments of the present invention will be explained in detail with reference to the accompanying drawings.

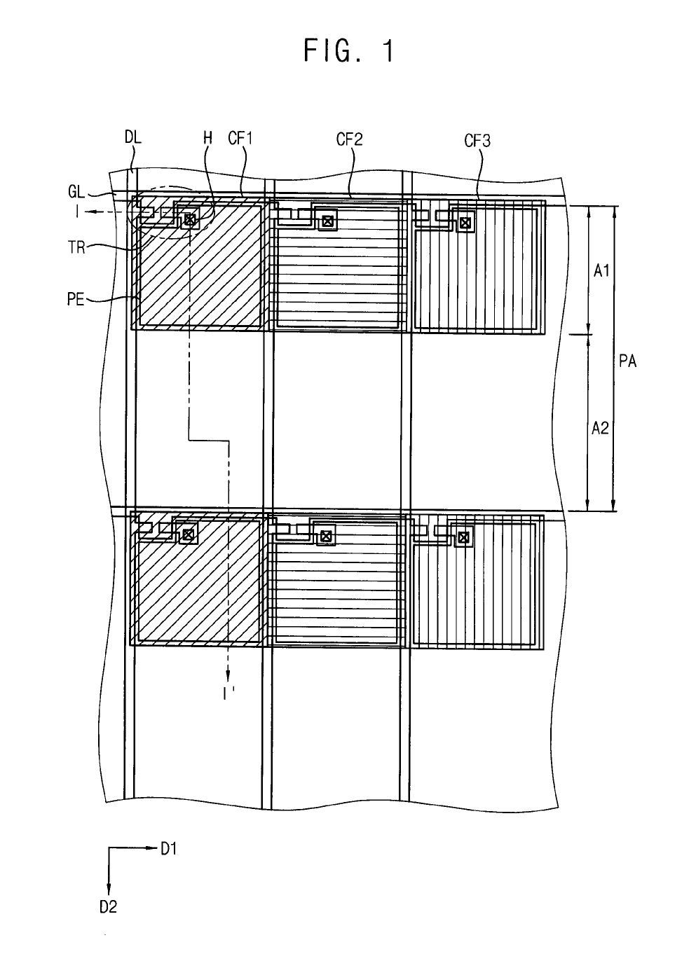

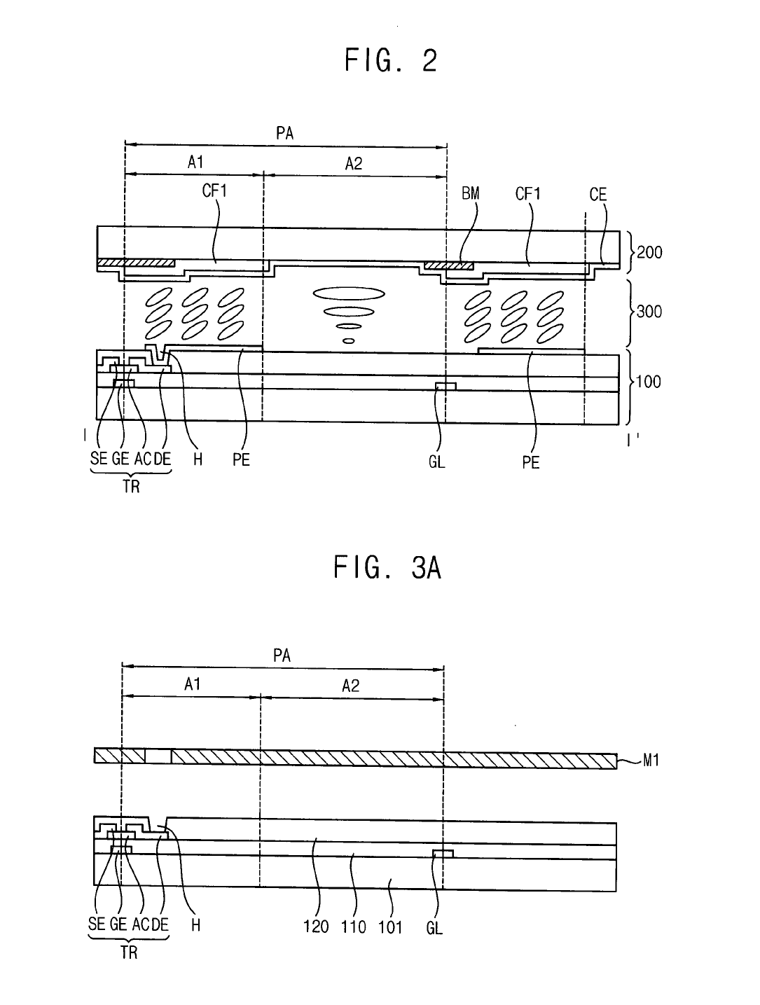

FIG. 1 is a plan view illustrating a display panel according to an exemplary embodiment. FIG. 2 is a cross-sectional view illustrating the display panel taken along line I-I′ as shown in FIG. 1.

Referring to FIGS. 1 and 2, the display panel may include, for example, a plurality of pixel areas PA, and each of the pixel areas PA is divided into a first area A1 and a second area A2. The display panel may include a first display substrate 100, a second display substrate 200 and a liquid crystal layer 300.

The first display substrate 100 may include, for example, a plurality of gate lines GL, a plurality of data lines DL, a plurality of transistors TR and a plurality of pixel electrodes PE.

The gate lines GL extend, for example, in a first direction D1 and are arranged in a second direction D2 crossing the first direction D1.

The data lines DL extend, for example, in the second direction D2 and are arranged in the first direction D1.

The transistors TR are connected to a gate line GL and a data line DL. The transistors TR may be disposed in an area adjacent to an area in which the gate line GL intersects with the data line DL.

The pixel electrodes PE are disposed in the first area A1 of the pixel area PA defined on the first display substrate 100. According to the present exemplary embodiment, the pixel electrode PE is not disposed in the second area A2 of the pixel area PA. The pixel electrodes PE is connected to the transistors TR through a contact hole H. The pixel electrode PE may include, for example, a transparent conductive material, such as indium tin oxide (ITO), indium zinc oxide (IZO), aluminum doped zinc oxide (AZO), cadmium zinc oxide (CZO) or amorphous indium tin oxide (a-ITO).

The second display substrate 200 may include, for example, a blocking pattern BM, a plurality of color filters CF1, CF2 and CF3 and a common electrode CE.

The blocking pattern BM is disposed corresponding to an area which surrounds the pixel area PA. For example, the blocking pattern BM may be disposed corresponding to areas in which the gate lines GL, the data lines DL and the transistors TR are disposed.

The color filters CF1, CF2 and CF3 may include, for example, a first color filter CF1, a second color filter CF2 and a third color filter CF3 which have a different color from each other. For example, the first, second and third color filters CF1, CF2 and CF3 are arranged adjacent to a color filter having a different color in the first direction D1 and are arranged adjacent to a color filter having a same color in the second direction D2. Each of the first, second and third color filters CF1, CF2 and CF3 is disposed corresponding to the first area A1 of the pixel area PA. In other words, according to the present exemplary embodiment, each of the color filters CF1, CF2 and CF3 is not disposed corresponding to the second area A2 of the pixel area PA.

The common electrode CE is opposite to the pixel electrodes PE and forms an electric field together with the pixel electrodes PE. The common electrode CE may include, for example, a transparent conductive material, such as indium tin oxide (ITO), indium zinc oxide (IZO), aluminum doped zinc oxide (AZO), cadmium zinc oxide (CZO) or amorphous indium tin oxide (a-ITO). The liquid crystal layer 300 may be arranged by the electric field formed between the common electrode CE and the pixel electrode PE so that a grayscale is displayed.

The liquid crystal layer 300 is disposed between the first and second display substrates 100 and 200, and the liquid crystal layer 300 may be driven with a normally white mode.

When a potential difference between the common electrode CE and the pixel electrode PE is a minimum that is an initial state of the liquid crystal layer 300, a white grayscale may be displayed. When the potential difference between the common electrode CE and the pixel electrode PE is a maximum, a black grayscale may be displayed. When the potential difference is between the minimum and the maximum, a middle grayscale may be displayed.

According to the present exemplary embodiment, the liquid crystal layer 300 in the first area A1 in which the pixel electrode PE is disposed, is displayed in a grayscale in response to a data voltage which is applied to the pixel electrode PE. However, the liquid crystal layer 300 in the second area A2 in which the pixel electrode PE is not disposed, is displayed in a white grayscale. The data voltage is not applied to the liquid crystal layer 300 in the second area A2 and thus, the liquid crystal layer 300 in the second area A2 may be maintained as the initial state. Therefore, the pixel area PA which has the first and second areas A1 and A2 may display a middle grayscale having increased transparency so that the display panel may have increased transparency and clarity. In addition, the pixel electrode PE is not disposed in the second area A2 so that the transmittance of the light which is provided from the backlight assembly may be increased.

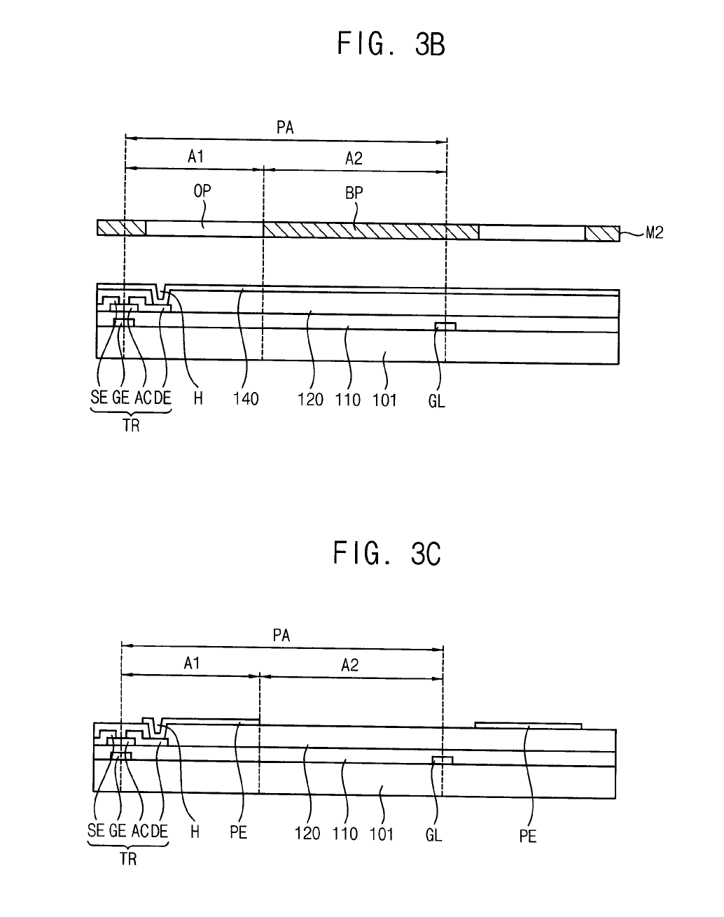

FIGS. 3A to 3C are cross-sectional views explaining a method of manufacturing a first display substrate as shown in FIG. 2.

Referring to FIGS. 2 and 3A, a first metal layer is formed on a base substrate 101. The first base substrate 101 may include, for example, any one selected from the group consisting of glass, quartz, or plastic. Further, in an embodiment, the first base substrate 101 may be, for example, a flexible substrate. Suitable materials for the flexible substrate include, for example, polyethylenenaphthalate, polyethylene terephthalate, polyacryl, polyimide, polyethersulfone, polyvinyl chloride, and a mixture thereof.

The first metal layer is pattered to form a first metal pattern. The first metal layer may include, for example, a metal such as chromium (Cr), aluminum (Al), tantalum (Ta), molybdenum (Mo), titanium (Ti), tungsten (W), copper (Cu), silver (Ag), etc., or an alloy thereof. The first metal layer may include, for example, two or more layers each having different physical characteristics from each other. The first metal pattern may include, for example, the gate line GL and the gate electrode GE of the transistor TR.

A first insulating layer 110 is formed on the base substrate 101 on which the first metal pattern is formed. The first insulating layer 110 may include, for example, silicon oxide (SiOx), silicon nitride (SiNx) or silicon oxynitride (SiON).

An active layer is formed on the base substrate 101 on which the first insulating layer 110 is formed. The active layer is patterned to form an active pattern AC on the gate electrode GE. The active pattern AC may include, for example, amorphous silicon (a-Si:H) or an oxide semiconductor.

For example, the active pattern AC may include a semiconductor layer comprised of amorphous silicon (a-Si:H) and an ohmic contact layer comprised of an n+ amorphous silicon (n+a-Si:H). In addition, the active pattern AC may include, for example, an oxide semiconductor. The oxide semiconductor may include, for example, an amorphous oxide including at least one selected from indium (In), zinc (Zn), gallium (Ga), tin (Sn) and hafnium (Hf). For example, the oxide semiconductor may comprise an amorphous oxide including indium (In), zinc (Zn) and gallium (Ga), or an amorphous oxide including indium (In), zinc (Zn) and hafnium (Hf). The oxide semiconductor may include, for example, an oxide such as indium zinc oxide (InZnO), indium gallium oxide (InGaO), indium tin oxide (InSnO), zinc tin oxide (ZnSnO), gallium tin oxide (GaSnO) and gallium zinc oxide (GaZnO). For example, the active pattern AC may include indium gallium zinc oxide (IGZO).

For example, when the active pattern AC includes the oxide semiconductor, an etch stopper may be disposed on the active pattern AC in a spacing area between the source electrode SE and the drain electrode DE.

A second metal layer is formed on the base substrate 101 on which the active pattern AC is formed. The second metal layer may include, for example, a metal such as chromium (Cr), aluminum (Al), tantalum (Ta), molybdenum (Mo), titanium (Ti), tungsten (W), copper (Cu), silver (Ag), etc., or an alloy thereof. The second metal layer may include, for example, two or more layers each having different physical characteristics from each other. The second metal layer is patterned to form a second metal pattern. The second metal pattern may include, for example, the source electrode SE and the drain electrode DE of the transistor TR, and the data line DL.

A second insulating layer 120 is formed on the base substrate 101 on which the second metal pattern is formed. The second insulating layer 120 may include, for example, silicon oxide (SiOx), silicon nitride (SiNx) or silicon oxynitride (SiON). In addition, the second insulating layer 120 may include, for example, two or more layers. For example, the second insulating layer 120 may include a protecting layer and an organic layer. The protecting layer may include, for example, silicon oxide (SiOx) and silicon nitride (SiNx). The organic layer may be, for example, thick so that a parasitic capacitance between the second metal pattern and the pixel electrode PE may be decreased.

A first mask M1 is disposed on the base substrate 101 on which the second insulating layer 120 is formed, to form a contact hole H. The second insulating layer 120 is, for example, etched through the first mask M1 and thus the contact hole H is formed in the second insulating layer 120 so that the drain electrode DE of the transistor TR is exposed via the contact hole H.

Referring to FIGS. 2, 3B and 3C, a transparent conductive layer 140 is formed on the base substrate 101 on which the contact hole H is formed. The transparent conductive layer 140 may include, for example, indium tin oxide (ITO), indium zinc oxide (IZO), aluminum doped zinc oxide (AZO), cadmium zinc oxide (CZO) or amorphous indium tin oxide (a-ITO). The transparent conductive layer 140 is in contact with the drain electrode DE via the contact hole H.

A second mask M2 is disposed on the base substrate 101 on which the transparent conductive layer 140 is formed. The transparent conductive layer 140 is, for example, patterned through the second mask M2 to form the pixel electrode PE which is connected to the drain electrode DE via the contact hole H. For example, the second mask M2 may include an opening part OP and a blocking part BP. The opening part OP may be disposed corresponding to the first area A1 in which the pixel electrode PE is formed. The blocking part BP may be disposed corresponding to the second area A2 in which the pixel electrode PE is not formed.

The transparent conductive layer 140 is, for example, patterned through the second mask M2 and thus, the transparent conductive layer 140 in the first area A1 remains as the pixel electrode PE and the transparent conductive layer 140 in the second area A2 may be etched. The first and second masks M1 and M2 are a mask for patterning a photoresist layer. For example, in an embodiment, the photoresist layer may be formed on a layer such as the insulating layer (e.g., second insulating layer 120) and the transparent conductive layer (e.g., transparent conductive layer 140). In addition, the photoresist layer may be, for example, patterned through the mask (e.g., first and second masks M1 and M2) to form a photoresist pattern, and the layer such as the insulating layer (e.g., second insulating layer 120) and the transparent conductive layer (e.g., transparent conductive layer 140) may be patterned through the photoresist pattern.

As shown in FIG. 3C, the transparent conductive layer 140 in the second area A2 of the base substrate 101 is etched so that the transmittance of the base substrate 101 may be increased.

According to the present exemplary embodiment, the pixel electrode PE is not formed in the second area A2 of the pixel area PA so that the second area A2 of the pixel area PA may display a white grayscale that is the initial state, unrelated to the data voltage applied to the pixel electrode PE. Therefore, the pixel area PA which has the first and second areas A1 and A2 may display a middle grayscale having increased transparency so that the display panel may have increased transparency and clarity. Thus, the display quality of an image displayed on the display panel may be increased.

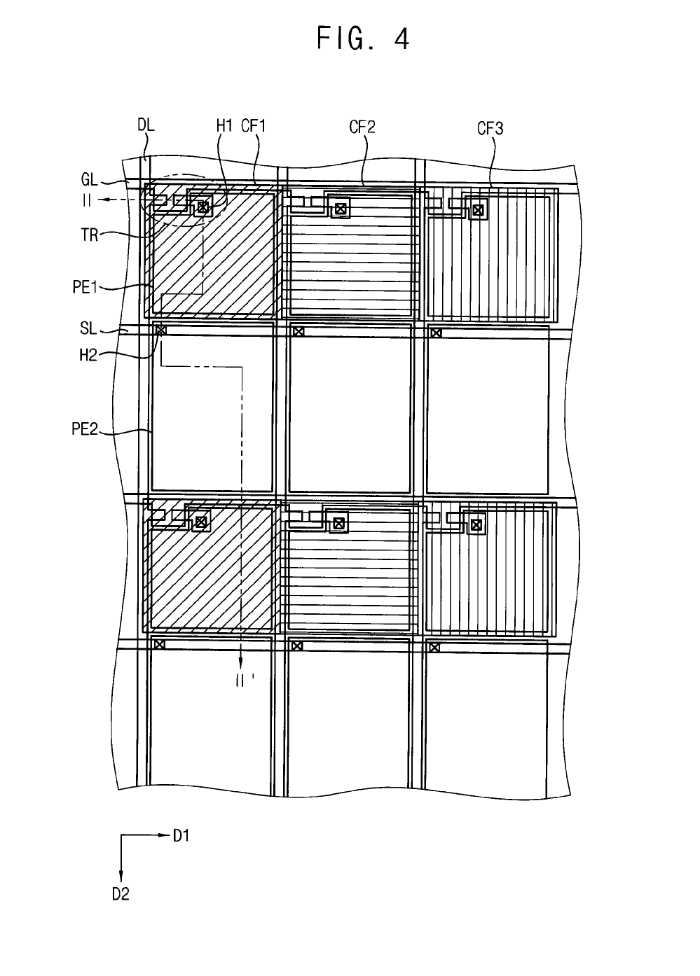

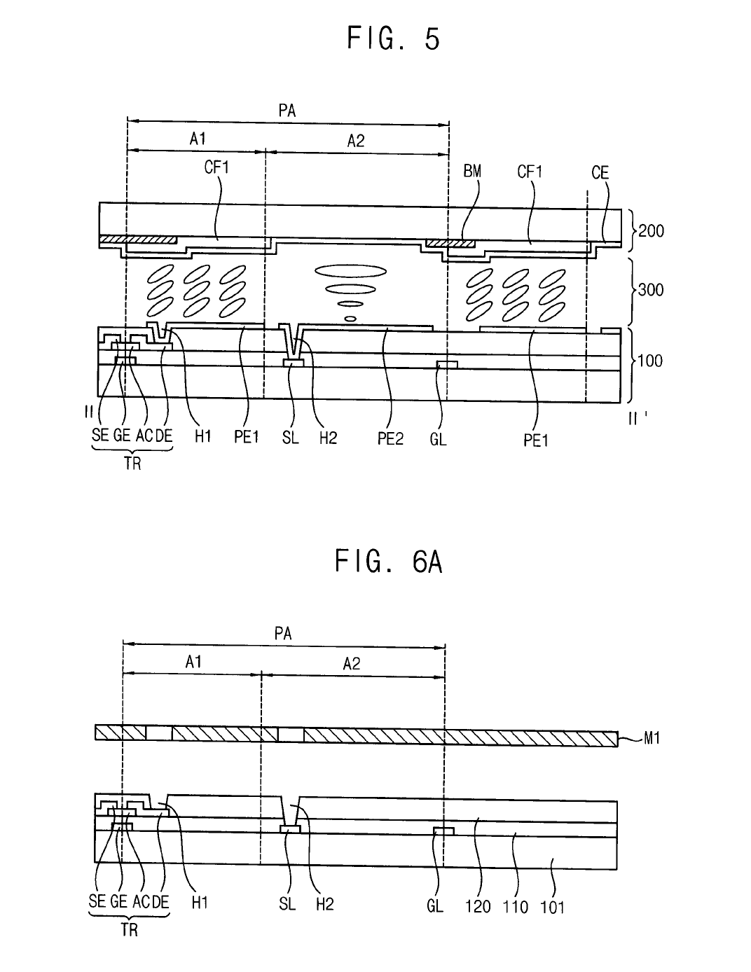

FIG. 4 is a plan view illustrating a display panel according to an exemplary embodiment. FIG. 5 is cross-sectional view illustrating the display panel taken along line II-II′ as shown in FIG. 4.

Referring to FIGS. 4 and 5, the display panel may include, for example, a plurality of pixel areas, and each of the pixel areas PA is divided a first area A1 and a second area A2. The display panel may include a first display substrate 100, a second display substrate 200 and a liquid crystal layer 300.

The first display substrate 100 may include, for example, a plurality of gate lines GL, a plurality of signal lines SL, a plurality of data lines DL, a plurality of transistors TR, a plurality of first pixel electrodes PE1 and a plurality of second pixel electrodes PE2.

The gate lines GL extend, for example, in a first direction D1 and are arranged in a second direction D2 crossing the first direction D1.

The signal lines SL are disposed between the gate lines GL. The signal lines SL extend, for example, in a first direction D1 and are arranged in a second direction D2 crossing the first direction D1.

The data lines DL extend, for example, in the second direction D2 and are arranged in the first direction D1.

The transistors TR is connected to a gate line GL and a data line DL. The transistors TR may be disposed in an area adjacent to an area in which the gate line GL crosses the data line DL.

Each of the first pixel electrodes PE1 is disposed in the first area A1 of the pixel area PA defined on the first display substrate 100. The first pixel electrode PE1 is connected to the transistor TR through a first contact hole H1.

Each of the second pixel electrodes PE2 is disposed in the second area A2 of the pixel area PA defined on the first display substrate 100. The second pixel electrode PE2 is connected to the signal lines SL through a second contact hole H2. The first pixel electrode PE1 and the second pixel electrode PE2 may each include, for example, a transparent conductive material, such as indium tin oxide (ITO), indium zinc oxide (IZO), aluminum doped zinc oxide (AZO), cadmium zinc oxide (CZO) or amorphous indium tin oxide (a-ITO).

The second display substrate 200 may include, for example, a blocking pattern BM, a plurality of color filters CF1, CF2 and CF3 and a common electrode CE.

The blocking pattern BM is disposed corresponding to an area which surrounds the pixel area PA. For example, the blocking pattern BM may be disposed corresponding to areas in which the gate lines GL, the data lines DL and the transistors TR are disposed.

The color filters CF1, CF2 and CF3 may include, for example, a first color filter CF1, a second color filter CF2 and a third color filter CF3 which have a different color from each other. The first, second and third color filters CF1, CF2 and CF3 are, for example, arranged adjacent to a color filter having a different color in the first direction D1 and are arranged adjacent to a color filter having a same color in the second direction D2. Each of the first, second and third color filters CF1, CF2 and CF3 is disposed corresponding to the first area A1 of the pixel area PA. In other words, according to the present exemplary embodiment, each of the first, second and third color filters CF1, CF2 and CF3 is not disposed corresponding to the second area A2 of the pixel area PA.

The common electrode CE is opposite to the first and second pixel electrodes PE1 and PE2 and forms an electric field together with the first and second pixel electrodes PE1 and PE2. The common electrode CE may include, for example, a transparent conductive material, such as indium tin oxide (ITO), indium zinc oxide (IZO), aluminum doped zinc oxide (AZO), cadmium zinc oxide (CZO) or amorphous indium tin oxide (a-ITO). The liquid crystal layer 300 may be arranged by the electric field formed between the common electrode CE and the first and second pixel electrodes PE1 and PE2 so that a grayscale is displayed.

The liquid crystal layer 300 is disposed between the first and second display substrates 100 and 200, and the liquid crystal layer 300 may be driven with a normally white mode or a normally black mode.

According to the present exemplary embodiment, the liquid crystal layer 300 in the first area A1 in which the first pixel electrode PE1 is disposed, is displayed in a grayscale in response to a data voltage which is applied to the first pixel electrode PE1. The liquid crystal layer 300 in the second area A2 in which the second pixel electrode PE2 is disposed, is displayed in a predetermined grayscale in response to a predetermined voltage which is applied to the second pixel electrode PE2. For example, when a black grayscale voltage is applied to the second pixel electrode PE2 through the signal line SL, the liquid crystal layer 300 in the second area A2 displays a black grayscale in response to the black grayscale voltage. Alternatively, when a white grayscale voltage is applied to the second pixel electrode PE2 through the signal line SL, the liquid crystal layer 300 in the second area A2 displays a white grayscale in response to the white grayscale voltage.

According to the present exemplary embodiment, the black grayscale voltage is applied to the second pixel electrode PE2 through the signal line SL such that the pixel area PA displays a black image. Thus, the pixel area PA may display a full black image.

In addition, according to the present exemplary embodiment, the second area A2 of the pixel area PA may display a predetermined grayscale which is preset by a customer. For example, when the second area A2 displays the white grayscale, the transparency of the middle grayscale may be increased as described above in connection with the display panel of FIG. 1. Alternatively, when the second area A2 displays the black grayscale, the full black image may be displayed.

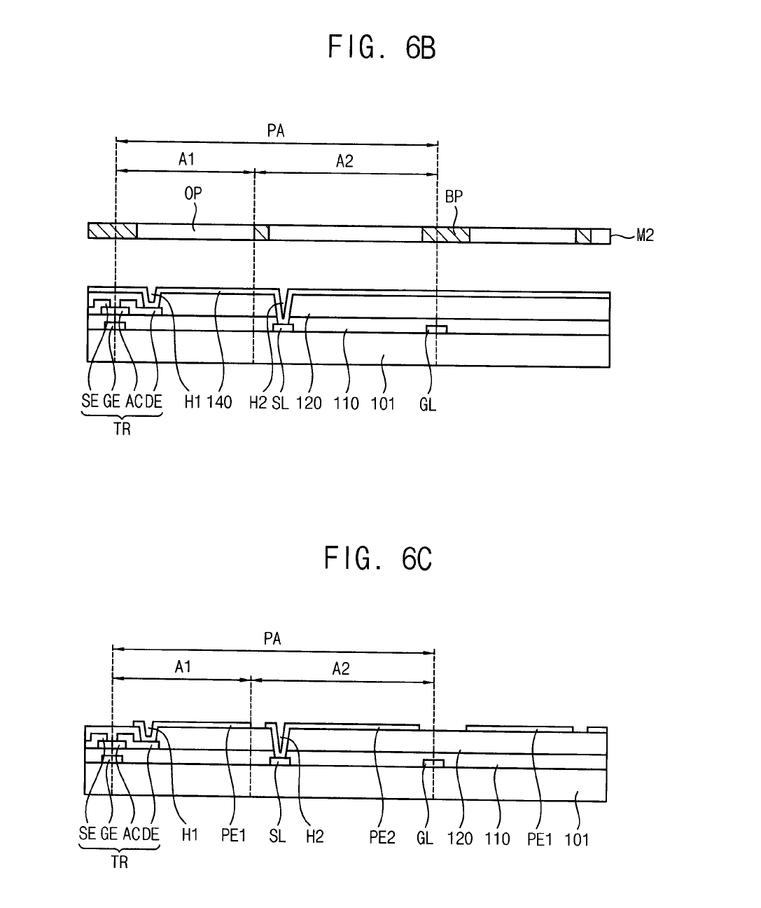

FIGS. 6A to 6C are cross-sectional views explaining a method of manufacturing a first display substrate as shown in FIG. 5.

Referring to FIGS. 5 and 6A, a first metal layer is formed on a base substrate 101. The first base substrate 101 may include, for example, any one selected from the group consisting of glass, quartz, or plastic. Further, in an embodiment, the first base substrate 101 may be, for example, a flexible substrate. Suitable materials for the flexible substrate include, for example, polyethylenenaphthalate, polyethylene terephthalate, polyacryl, polyimide, polyethersulfone, polyvinyl chloride, and a mixture thereof.

The first metal layer is pattered to form a first metal pattern. The first metal layer may include, for example, a metal such as chromium (Cr), aluminum (Al), tantalum (Ta), molybdenum (Mo), titanium (Ti), tungsten (W), copper (Cu), silver (Ag), etc., or an alloy thereof. The first metal layer may include, for example, two or more layers each having different physical characteristics from each other. The first metal pattern may include, for example, the gate line GL, the signal line SL, and the gate electrode GE of the transistor TR.

A first insulating layer 110 is formed on the base substrate 101 on which the first metal pattern is formed. The first insulating layer 110 may include, for example, silicon oxide (SiOx), silicon nitride (SiNx) or silicon oxynitride (SiON).

An active layer is formed on the base substrate 101 on which the first insulating layer 110 is formed. The active layer is patterned to form an active pattern AC on the gate electrode GE. The active pattern AC may include, for example, amorphous silicon (a-Si:H) or an oxide semiconductor.

For example, when the active pattern AC includes the oxide semiconductor, an etch stopper may be disposed on the active pattern AC in a spacing area between the source electrode SE and the drain electrode DE.

A second metal layer is formed on the base substrate 101 on which the active pattern AC is formed. The second metal layer may include, for example, a metal such as chromium (Cr), aluminum (Al), tantalum (Ta), molybdenum (Mo), titanium (Ti), tungsten (W), copper (Cu), silver (Ag), etc., or an alloy thereof. The second metal layer may include, for example, two or more layers each having different physical characteristics from each other. The second metal layer is patterned to form a second metal pattern. The second metal pattern may include, for example, the source electrode SE and the drain electrode DE of the transistor TR, and the data line DL.

A second insulating layer 120 is formed on the base substrate 101 on which the second metal pattern is formed. The second insulating layer 120 may include, for example, silicon oxide (SiOx), silicon nitride (SiNx) or silicon oxynitride (SiON). In addition, the second insulating layer 120 may include, for example, two or more layers. For example, the second insulating layer 120 may include a protecting layer and an organic layer. The protecting layer may include, for example, silicon oxide (SiOx) and silicon nitride (SiNx). The organic layer may be, for example, thick so that a parasitic capacitance between the second metal pattern and the pixel electrode PE may be decreased.

A first mask M1 is disposed on the base substrate 101 on which the second insulating layer 120 is formed to form a first contact hole H1 and a second contact hole H2. The second insulating layer 120 is, for example, etched through the first mask M1 and thus the first contact hole H1 is formed in the second insulating layer 120 so that the drain electrode DE of the transistor TR is exposed via the first contact hole H1. In addition, the first and second insulating layers 110 and 120 are, for example, etched through the first mask M1 and thus the second contact hole H2 is formed in the first and second insulating layers 110 and 120 so that the signal line SL is exposed via the second contact hole H2.

Referring to FIGS. 5, 6B and 6C, a transparent conductive layer 140 is formed on the base substrate 101 on which the first and second contact holes H1 and H2 are formed. The transparent conductive layer 140 may include, for example, indium tin oxide (ITO), indium zinc oxide (IZO), aluminum doped zinc oxide (AZO), cadmium zinc oxide (CZO) or amorphous indium tin oxide (a-ITO). The transparent conductive layer 140 is in contact with the drain electrode DE via the first contact hole H1 and the signal line SL via the second contact hole H2.

A second mask M2 is disposed on the base substrate 101 on which the transparent conductive layer 140 is formed. The transparent conductive layer 140 is patterned through, for example, the second mask M2 to form the first pixel electrode PE1 which is connected to the drain electrode DE via the first contact hole H1 and the second pixel electrode PE2 which is connected to the signal line SL via the second contact hole H2. For example, the second mask M2 may include an opening part OP and a blocking part BP. The opening part OP may be disposed, for example, corresponding to the first and second areas A1 and A2 in which the first and second pixel electrodes PE1 and PE2 are formed. The blocking part BP may be disposed, for example, corresponding to the second area A2 in which the first and second pixel electrodes PE1 and PE2 are not formed.

The transparent conductive layer 140 is, for example, patterned through the second mask M2 and thus, the first pixel electrode PH is formed in the first area A1 and the second pixel electrode PE2 is formed in the second area A2.

According to the present exemplary embodiment, as shown in FIG. 6C, the second pixel electrode PE2 is spaced apart from the first pixel electrode PE1 and is directly contacted with the signal line SL via the second contact hole H2. Thus, the second pixel electrode PE2 may be driven without a transistor TR.

According to the present exemplary embodiment, the second pixel electrode PE2 which is connected to the signal line SL is disposed in the second area A2 of the pixel area PA and thus, the second pixel electrode PE2 may be driven without a transistor TR. Therefore, a grayscale voltage applied to second pixel electrode PE2 may be adjusted so that the second area A2 may display a white grayscale to increase the transparency of a middle grayscale. Alternatively, the second area A2 may display a black grayscale to display a full black image. Thus, the display quality of an image displayed on the display panel may be increased.

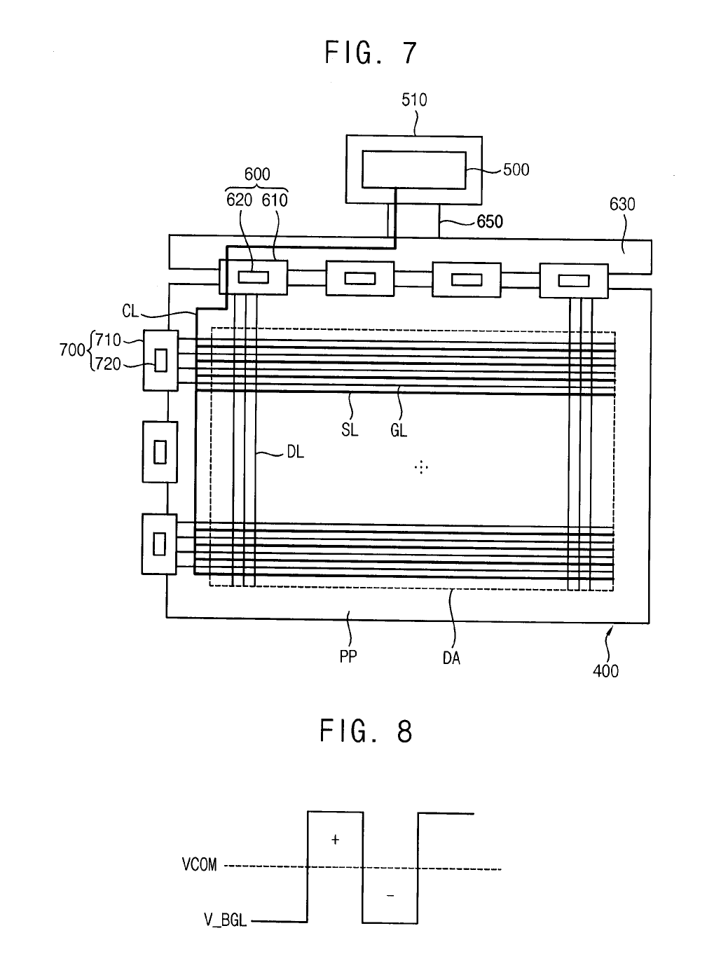

FIG. 7 is a plan view illustrating a display apparatus according to an exemplary embodiment. FIG. 8 is a waveform view illustrating a method of driving the display panel shown in FIG. 5.

Referring to FIGS. 5 and 7, the display apparatus may include a display panel 400 and a panel driving part.

As shown in FIG. 5, the display panel 400 may include, for example, a plurality of gate lines GL, a plurality of signal lines SL and a plurality of data lines DL which are disposed in a display area DA.

A connection line CL and a panel driving part are disposed in a peripheral area PP surrounding the display area DA.

The connection line CL is commonly connected to end portions of the signal lines SL. The connection line CL is electrically connected to the main driving part 500 through a data flexible circuit board 610, and transfers a driving signal received from the main driving part 500 to the signal lines SL. Thus, the signal lines SL may concurrently receive the driving signal.

The panel driving part may include, for example, the main driving part 500, a data driving part 600 and a gate driving part 700.

The main driving part 500 is disposed on a main printed circuit board 510. The main driving part 500 controls the operation of the display panel 400, the data driving part 600 and the gate driving part 700.

The data driving part 600 may include, for example, the data flexible circuit board 610 and a data driver chip 620 which is disposed on the data flexible circuit board 610. The data driving part 600 is electrically connected to the main driving part 500 through a source printed circuit board 630 and a flexible circuit film 650. The data driving part 600 converts image data received from the main driving part 600 to a data voltage and outputs the data voltage to the data line DL.

The gate driving part 700 may include, for example, a gate flexible circuit board 710 and a gate driver chip 720 which is disposed on the gate flexible circuit board 710. The gate driver chip 720 receives a gate control signal outputted from the main driving part 500 through the data flexible circuit board 610. The gate driving part 700 generates a gate signal and outputs the gate signal to the gate line GL.

According to the present exemplary embodiment, the main driving part 500 provides the signal lines SL of the display panel 400 with the driving signal. The driving signal may be preset such as a black grayscale voltage, a white grayscale voltage, a middle grayscale voltage, etc.

For example, as shown in FIG. 8, the main driving part 500 provides the signal lines SL with a black grayscale voltage V_BGL. The main driving part 500 provides the common electrode CE with a common voltage VCOM. In the present exemplary embodiment, the liquid crystal layer is driven with the normally white mode so that a potential difference between the black grayscale voltage V_BGL and the common voltage VCOM is a maximum. The black grayscale voltage V_BGL may alternate a positive polarity and a negative polarity opposite to the positive polarity with respect to the common voltage VCOM by a predetermined period according to an inversion mode of the display panel 400. However, alternatively, the black grayscale voltage V_BGL may be a constant voltage unrelated to the inversion mode of the display panel 400.

According to the present exemplary embodiment, the signal lines SL of the display area DA may be connected as one through the connection line CL of the peripheral area PP. Thus, the driving signal is concurrently applied to the second pixel electrodes PE2 shown in FIG. 5.

According to exemplary embodiments of the present invention, the pixel electrode PE is disposed in the first area A1 of the pixel area PA so that the second area A2 of the pixel area PA may display a white grayscale that is the initial state unrelated to the data voltage applied to the pixel electrode PE. Thus, the transparency of a middle grayscale displayed on the pixel area PA may be increased and the transmittance of the pixel area PA may be increased. In addition, the second pixel electrode PE2 which is connected to the signal line SL is disposed in the second area A2 of the pixel area PA so that the second pixel electrode PE2 may drive independently from the first pixel electrode PE1 in the first area A1 of the pixel area PA. Thus, when the second area A2 displays the white grayscale, the transparency of the middle grayscale may be increased. Alternatively, when the second area A2 displays a black grayscale, a full black image may be displayed. Thus, the display quality of an image displayed on the display panel may be increased.

Having described exemplary embodiments of the present invention, it is further noted that it is readily apparent to those of ordinary skill in the art that various modifications may be made without departing from the spirit and scope of the invention which is defined by the metes and bounds of the appended claims.

What is claimed is:

1. A method of manufacturing a display substrate, the method comprising:
forming a plurality of gate lines, a plurality of data lines and a plurality of transistors on a base substrate;
forming an insulating layer on the base substrate on which the transistors are formed; and
forming a first pixel electrode on the insulating layer in a first area of a pixel area, wherein the pixel area is divided into the first area and a second area.

2. The method of claim 1, wherein the forming of the first pixel electrode comprises:
forming a first contact hole in the insulating layer to expose a drain electrode of one of the transistors;
forming a transparent conductive layer on the base substrate on which the first contact hole is formed; and
patterning the transparent conductive layer to form the first pixel electrode on the insulating layer in the first area and to expose the insulating layer in the second area.

3. The method of claim 1, wherein the forming of the plurality of transistors comprises:
forming a plurality of signal lines which are disposed between the gate lines.

4. The method of claim 3, wherein the plurality of signal lines are formed from a same metal layer as the gate lines.

5. The method of claim 1, wherein the forming of the first pixel electrode comprises:
forming a first contact hole in the insulating layer to expose a drain electrode of one of the transistors;
forming a second contact hole in the insulating layer to expose a signal line disposed between the gate lines;
forming a transparent conductive layer on the base substrate on which the first contact hole and the second contact hole are formed; and
patterning the transparent conductive layer to form the first pixel electrode on the insulating layer in the first area and to form a second pixel electrode on the insulating layer in the second area.

6. The method of claim 5, wherein the first pixel electrode is connected to the drain electrode of the one of the transistors through the first contact hole, and wherein the second pixel electrode is connected to the signal line through the second contact hole.

7. The method of claim 5, wherein the forming of the plurality of transistors comprises:
forming a connection line which is connected to an end portion of the signal line.

8. A display panel comprising:
a first display substrate comprising a first pixel electrode which is disposed in a first area of a pixel area, and a transistor which is connected to the first pixel electrode, wherein the pixel area is divided into the first area and a second area;
a second display substrate comprising a color filter which is disposed in an area corresponding to the first area of the pixel area; and
a liquid crystal layer disposed between the first and second display substrates.

9. The display panel of claim 8, wherein the liquid crystal layer has a normally white mode.

10. The display panel of claim 9, wherein the first display substrate further comprises an insulating layer which is disposed between the first pixel electrode and the transistor, and
wherein the second display substrate further comprises a common electrode.

11. The display panel of claim 10, wherein the liquid crystal layer in the first area is disposed between the common electrode and the first pixel electrode, and wherein the liquid crystal layer in the second area is disposed between the common electrode and the insulating layer.

12. The display panel of claim 8, wherein the first display substrate further comprises a gate line which is connected to a gate electrode of the transistor and a data line which is connected to a source electrode of the transistor,
wherein the first pixel electrode is connected to a drain electrode of the transistor through a first contact hole.

13. The display panel of claim 12, wherein the first display substrate further comprises a signal line which is disposed between the gate lines; and
a second pixel electrode spaced apart from the first pixel electrode, and wherein the second pixel electrode is disposed in the second area and is connected to the signal line through a second contact hole.

14. The display panel of claim 12, wherein the first display substrate further comprises a plurality of signal lines and a connection line which is connected to end portions of the signal lines.

15. A display apparatus comprising:
a display panel comprising a first display substrate which comprises a first pixel electrode disposed in a first area of a pixel area and a transistor which is connected to the first pixel electrode, wherein the pixel area is divided into the first area and a second area, and a second display substrate which comprises a color filter overlapping with the first pixel electrode and disposed in the first area; and
a main driving part configured to drive the display panel.

16. The display apparatus of claim 15, wherein the display panel further comprises a liquid crystal layer which is disposed between the first and second display substrates and has a normally white mode.

17. The display apparatus of claim 15, wherein the display panel further comprises a second pixel electrode which is spaced apart from the first pixel electrode and disposed in the second area.

18. The display apparatus of claim 17, wherein the display panel further comprises:
a gate line which is connected to the transistor;
a data line which crosses the gate line; and
a signal line which is disposed between the gate lines and is connected to the second pixel electrode.

19. The display apparatus of claim 18, wherein the second pixel electrode is connected to the signal line through a contact hole.

20. The display apparatus of claim 18, wherein the display panel further comprises:
a connection line which is connected to end portions of a plurality of signal lines, and
wherein the main driving part is configured to provide the connection line with a driving signal to drive the second pixel electrode.
